(19) United States
(12) Patent Application Publication
(10) Pub. No.: US 2024/0195040 A1
(43) Pub. Date: Jun. 13, 2024

(54) Self-Tuning Resonant Cavity RF Transmitter Combiner with Extended Tuning Frequency Range

(71) Applicant: Norsat International Inc., Richmond (CA)

(72) Inventor: Michael Jerome Macki, Richmond Hill (CA)

(73) Assignee: Norsat International Inc., Richmond (CA)

(21) Appl. No.: 18/078,994

(22) Filed: Dec. 11, 2022

(51) Int. Cl. H01P 5/18; H01P 1/207

(52) U.S. Cl. CPC H01P 5/18; H01P 1/207

(57) ABSTRACT

A self-tuning, resonant cavity transmitter combiner joins multiple RF transmitters and combines their signals onto a single transmission line. An additional tuning element is added to the junction of the signal paths to overcome the bandwidth limitations of the transmission lines joining the signal paths. An algorithm was developed to optimize the RF performance of the combiner by sampling the RF signals at various points in the RF circuit.

### BACKGROUND OF THE INVENTION

### 1. Field of Invention

This invention pertains to RF signal conditioning products that combine the signals from multiple RF transmitters on to a single transmission line.

### 2. Description of Related Art

A transmitter combiner allows multiple transmitters to share a single antenna or signal path. The resonant cavity in each signal path is tuned to the frequency of its corresponding transmitter. Self tuning combiners sample the signals from the transmitters and tune the cavities to resonate at these frequencies without input from the user. The outputs of each resonant cavity are joined to a common junction using transmission lines. The length of these lines depends on the frequencies of the transmitters. This limits the operating frequency range of the combiner as deviation from the original frequency for which the line was optimized can create excess loss of RF power within the combiner and sub-optimal performance.

An object of the invention is to address the above shortcomings.

### SUMMARY

The above shortcomings may be addressed by providing, in accordance with one aspect of the invention, a self-tuning transmitter combiner. The combiner includes: (a) a junction for combining a plurality of signals transmitted along a plurality of signal paths comprising a plurality of filters, respectively, the junction comprising a reactive element; and (b) a computer-implemented controller operable to tune the plurality of filters in accordance with a plurality of carrier frequencies of the plurality of signals, respectively, the controller being further operable to tune the reactive element such that a lowest insertion gain selected by the controller from a plurality of insertion gains respectively associated with the plurality of signal paths is maximized.

The controller may be operable to minimize a plurality of reflected powers of the plurality of filters by adjusting a plurality of cavity positions associated with the plurality of filters, respectively. The controller may be operable to determine, in response to a respective one carrier frequency, a corresponding one cavity position by interpolation among a plurality of known cavity positions respectively associated with a plurality of known carrier frequencies. The controller may be operable to set the reactive element to a midpoint tuning position of a range of tuning positions of the reactive element. The controller may be further operable to then determine a first lowest insertion gain. The controller may be operable to determine a first plurality of insertion gains associated with the plurality of signal paths respectively extending from a plurality of directional couplers of the combiner, through the plurality of filters, through the junction, and then to an output directional coupler of the combiner. The controller may be further operable to then select the first lowest insertion gain from the first plurality of insertion gains. The controller may be operable to: (c) set the reactive element to a new tuning position, within the range of the tuning positions, that is offset by a predetermined amount from a preceding tuning position of the tuning positions; (d) determine a new plurality of the insertion gains in response to the new tuning position; (e) determine a new lowest insertion gain in response to the new plurality of the insertion gains; and (f) iteratively repeat steps (c) to (e) until the new lowest insertion gain is lower than a preceding lowest insertion gain.

In accordance with another aspect of the invention, there is provided a method of tuning a combiner. The method involves: (a) by a computer-implemented controller, tuning a plurality of filters of a plurality of signal paths in accordance with a plurality of carrier frequencies of a plurality of signals being transmitted along the plurality of signal paths, respectively; and (b) by the computer-implemented controller, tuning a reactive element of a junction for combining the plurality of signals, such that a lowest insertion gain selected from a plurality of insertion gains respectively associated with the plurality of signal paths is maximized.

Step (a) may be performed before performing step (b). The method may further involve repeating step (a) after having performed step (b). Step (a) may involve minimizing a plurality of reflected powers of the plurality of filters by adjusting a plurality of cavity positions of the plurality of filters, respectively. Adjusting the plurality of cavity positions associated with the plurality of filters, respectively, may involve determining, in response to a respective one carrier frequency, a corresponding one cavity position by interpolating among a plurality of known cavity positions respectively associated with a plurality of known carrier frequencies. The method may further involve repeating the step of respectively minimizing the plurality of reflected powers of the plurality of filters. Step (b) may involve setting the reactive element to a midpoint tuning position of a range of tuning positions of the reactive element and then determining a first lowest insertion gain. Determining the first lowest insertion gain may involve determining a first plurality of the insertion gains associated with the plurality of signal paths extending from a plurality of input directional couplers of the combiner, through the plurality of filters, respectively, through the junction, and then to an output direction coupler of the combiner. The method may further involve selecting the first lowest insertion gain from the first plurality of the insertion gains. The method may further involve setting the reactive element to a second tuning position, within the range of the tuning positions, that is offset by a predetermined amount from the midpoint tuning position. The method may then further involve determining a second plurality of the insertion gains associated with the plurality of signal paths. The method may then further involve selecting a second lowest insertion gain from the second plurality of the insertion gains. The method may further involve changing the polarity of the predetermined amount if the second lowest insertion gain is lower than the first lowest insertion gain. The method may further involve: (c) setting the reactive element to a new tuning position, within the range of the tuning positions, that is offset by the predetermined amount from a preceding tuning position of the tuning positions; (d) determining a new plurality of the insertion gains in response to the new tuning position; (e) determining a new lowest insertion gain in response the new plurality of the insertion gains; and (f) iteratively repeating steps (c) to (e) until the new lowest insertion gain is lower than a preceding lowest insertion gain. The method may further involve receiving, by the computer-implemented controller, user instructions indicating manual override and, in response to the user instructions, performing at least one computer-implemented action selected from: (g) adjusting a cavity position of a user-selected filter; and (h) setting the reactive element to a user-selected tuning position within a range of tuning positions of the reactive element.

In accordance with another aspect of the invention, there is provided a self-tuning transmitter combiner. The combiner includes: (a) means for tuning a plurality of filters of a plurality of signal paths in accordance with a plurality of carrier frequencies of a plurality of signals being transmitted along the plurality of signal paths, respectively; and (b) means for tuning a reactive element of a junction for combining the plurality of signals, such that a lowest insertion gain selected from a plurality of insertion gains respectively associated with the plurality of signal paths is maximized.

The foregoing summary is illustrative only and is not intended to be in any way limiting. Other aspects and features of the present invention will become apparent to those of ordinary skill in the art upon review of the following description of embodiments of the invention in conjunction with the accompanying figures and claims.

### BRIEF DESCRIPTION OF THE DRAWINGS

In drawings which illustrate by way of example only embodiments of the invention:

FIG. 1 is a schematic diagram of the self tuning resonant cavity transmitter combiner;

FIG. 2 illustrates how certain components affect the combiner performance in the absence of a compensating reactive element;

FIG. 3 illustrates the performance of the combiner when the frequencies match the lengths of the transmission lines;

FIG. 4 illustrates how operating the combiner that is missing the compensating reactance at frequencies that do not match the transmission line lengths degrades the combiner's performance;

FIG. 5 illustrates how adding the reactive element can return the combiner's performance to closely match the ideal case;

FIG. 6 is a flowchart illustrating the tuning algorithm used by the combiner;

FIG. 7 is a flowchart of the “initial cavity tuning” sub-process;

FIG. 8 is a flowchart of the “optimize cavity tuning” sub-process; and

FIG. 9 is a flowchart of the “optimize junction tuning” sub-process.

### DETAILED DESCRIPTION

The embodiments of the present invention are described in detail with reference to the attached drawings.

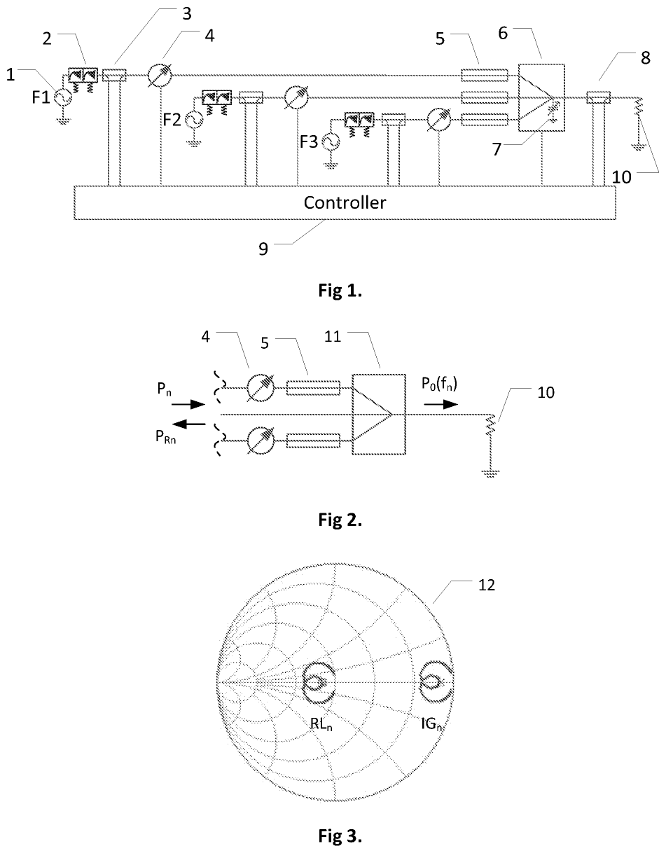

FIG. 1 is a schematic of the self tuning transmitter combiner. It illustrates how the components are connected in each signal path, how they are joined together into a single output and how each they are connected to the controller 9.

The embodiment shown in FIG. 1 comprises a number of signal paths equal to the number of channels that the combiner is required to support, a junction 6 (also referred herein to a junction block 6) with a tunable reactive element 7 (also referred herein to an electro-mechanical tunable reactive element 7 or reactive element 7), a final directional coupler 8 at the output of the combiner and a control unit such as the controller 9.

Three signal paths are shown for illustration, but embodiments of the invention can be adapted for many different numbers of paths. The RF sources 1 represent the radios which are external to the invention and the load 10 represents any additional equipment connected to the output of the invention.

Each signal path comprises an isolator 2, a directional coupler 3, an electro-mechanical tunable resonant cavity 4 (also referred herein to a tunable resonator 4, resonant cavity 4, or resonant cavity filter 4) and a fixed electrical length transmission line 5. The isolator's 2 purpose is to prevent any RF power from flowing back into the radio 1. The directional coupler 3 sends a small sample of the RF power travelling in the forward direction (away from the radio) and in the reverse direction (towards the radio) to the control unit 9. The tunable resonator 4, when adjusted to the correct frequency, filters out any extraneous signals that may have entered the signal path and maximizes the transmission of the desired signal. The fixed length transmission line 5, in conjunction with the tunable reactive element 7, acts as an impedance transformer. It minimizes the interference this signal path can cause to the signals transmitted through the other paths.

The junction block 6 connects the individual signal paths to a single output. The electro-mechanical tunable reactive element 7 optimizes the transmission of all the signals.

The final directional coupler 8 sends a small sample of the combined signals from all the signal paths traveling in the forward and reverse directions, respectively, to the control unit 9.

The controller 9 analyzes the signals from the directional couplers 3,8 and adjusts the tuning of the resonant cavities 4 using an electromechanical device. The controller 9 determines the frequency for each signal and its power level based on the samples sent from the directional couplers 3 in each path. The controller 9 uses a data set that relates the tuning element position for each resonant cavity 4 to its corresponding resonance frequency and interpolates the position required to match the measured frequency for each channel. Each tuning element of the resonant cavity 4 is then set to its corresponding position. The controller 9 then makes fine adjustments to the resonant cavities 4 to minimize any power reflected from the resonant cavities 4.

If the combiner was operating at a fixed set of frequencies, then the electrical lengths of the transmission lines 5 could be predetermined to maximize the power transmission through the combiner. This combiner allows the operator to change frequencies within a specified range so the lengths of the transmission lines will not be optimal. The reactive element 7 is set to compensate for the sub-optimal length of the transmission lines.

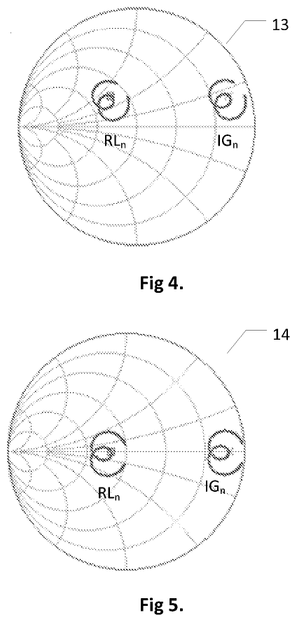

FIGS. 1 to 5 illustrate the use of a tuned reactance of a reactive element 7 in bringing the performance of non-ideal length transmission lines 5 in line with the performance of ideal transmission lines. With reference to FIG. 2, when the transmission lines 5 joining the resonant cavities 4 together are the ideal length for the channel frequencies the effects of the different resonant cavities 4 on the reflections at the junction 11 and the transmission through the junction 11 are respectively shown in FIG. 3. Thus, the (admittance) Smith Chart 12 in FIG. 3 shows the performance of the transmission path under ideal conditions. However, if the resonant cavities 4 are tuned to different frequencies, then the transmission lines 5 add a reactance to the junction 11 (FIG. 2) as illustrated by the reflection curves on the Smith Chart 13 (FIG. 4) being displaced from the purely resistive line on the chart into the reactive area. This adds additional reflections and reduces the transmitted power through the junction 11. Adding a reactance by the reactive element 7 (FIG. 1) that has the opposite sign and a magnitude that counterbalances the reactance of the transmission lines 5 returns the reflected and transmitted power curves back to the resistive line of the Smith Chart 14 (FIG. 5) and reduces the internal reflections while optimizing the transmission through the junction 6 (FIG. 1).

The effect of the transmission lines can be understood from FIG. 2 with reference to FIGS. 3 and 4. The Smith Chart 12 (FIG. 3) shows the reflections from and the transmission through the junction 11 when the transmission lines are the ideal length for the combiner frequencies. The curves for the reflection from and transmission through the junction 11 are on the resistive line for the Smith Chart 12 which corresponds to minimal reflection and maximum transmission. If the resonant cavities 4 in the combiner are tuned to a different frequency, then the transmission lines 5 are no longer optimal and add a reactance to the junction 11. This is illustrated in the FIG. 4 Smith Chart 13. The reflection and transmission curves have moved away from the resistive line and are now in the reactive region of the chart. Adding a reactance by the reactive element 7 (FIG. 1) that is the opposite sign and a magnitude that balances out the reactance of the transmission lines 5 returns the transmission and reflection curves to the resistive line (FIG. 5 Smith Chart 14). This minimizes the internal reflection and maximizes transmission. The method for determining this reactance of the reactive element 7 (FIG. 1) is described below.

The controller 9 (FIG. 1) first adjusts the tuning element for each resonant cavity 4 until the return loss for the corresponding resonant cavity 4 is minimized. The return loss is defined below:
RLₙ—return loss for the signal passing through resonant cavity n
fₙ—carrier frequency for signal path n.
Pₙ— power in the forward direction for signal path n at fₙ.
P_{Rn}— power reflected from resonant cavity n

$${RL}_{n} = \frac{{P}_{Rn}}{{P}_{n}}$$

The controller 9 determines a quantity called the insertion gain for each signal path according to the following:
IGₙ—insertion gain of signal path n.
Pₒ(fₙ)—forward power at the output at frequency fₙ.

$${IG}_{n} = \frac{{P}_{o} ( {f}_{n} )}{{P}_{n}}$$

The controller 9 adjusts the reactive element 7 until the lowest value of IGₙ is maximized.

The controller 9 will then readjust the tuning of the resonant cavities 4 to minimize their reflections and then do a final adjustment to the reactive element 7 to maximize the worst insertion gain. The tuning of one element in an RF circuit can affect the tuning of other elements in the circuit. The second tuning pass is done to compensate for this effect.

FIG. 3 shows the admittance Smith Chart that displays the return loss RLₙ and insertion gain IGₙ for signal path n when the frequencies transmitted through the combiner are well matched to the lengths of the transmission lines 5.

FIG. 4 shows the admittance Smith Chart that displays the return loss RLₙ and insertion gain IGₙ for signal path n when the frequencies transmitted through the combiner are not well matched to the lengths of the transmission lines 5.

FIG. 5 shows the admittance Smith Chart that displays the return loss RLₙ and insertion gain IGₙ for signal path n when a reactive element 7 (FIG. 1) is added to compensate for the discrepancy between the operating frequencies of the combiner and the lengths of the transmission lines 5.

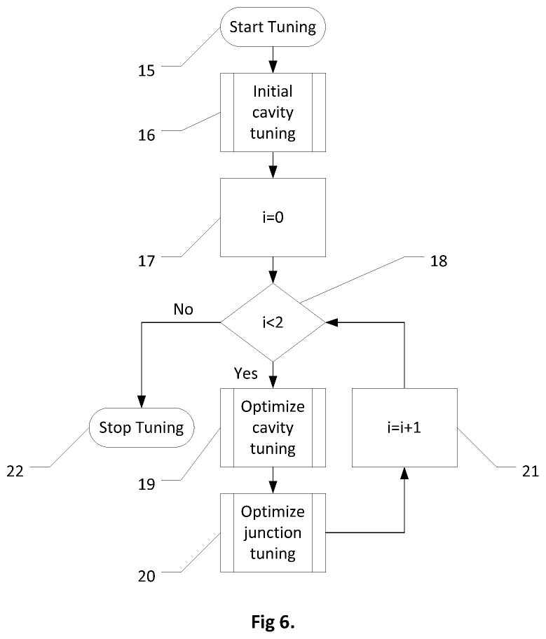

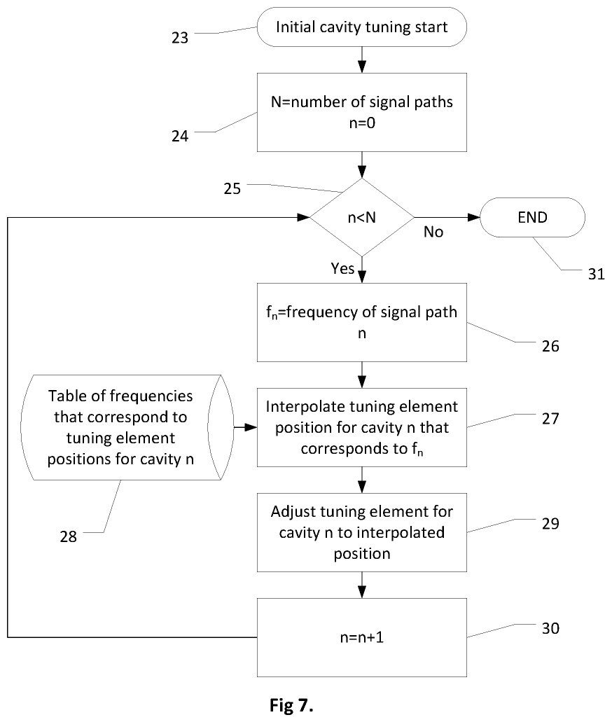

FIG. 6 is a flowchart showing the tuning algorithm for the combiner shown in FIG. 1. The process starts at step 15 when the combiner is first powered or when the controller 9 (FIG. 1) determines that the frequencies for one or more of the radios 1 have changed. The “initial cavity tuning” sub-process 16 is called. The loop counter is initialized at step 17. The “optimize cavity tuning” sub-process 19 is called. The “optimize junction tuning” sub-process 20 is called. The loop counter is incremented at step 21. These processes 19, 20 are repeated a second time as the adjustment of a tuning element of a resonant cavity 4 can affect the performance of a previously tuned element and this second pass compensates for this effect. The loop counter is incremented again at step 21. The escape condition determined at step 18 for the loop is met and the algorithm stops at step 22. Additional information for the tuning sub-processes is provided in FIGS. 7, 8 and 9.

FIG. 7 is a flowchart of the “initial cavity tuning” sub-process. This sub-process starts at step 23 when called by the main tuning algorithm of FIG. 6. The number of signal paths is defined and the loop counter is initialized at step 24. First the carrier frequency of the signal sent down the first signal path is determined at step 26. There is a table 28 that lists the resonance frequency of each resonant cavity 4 that corresponds to the position of the tuning element of the resonant cavity 4. Interpolation is used at step 27 to determine the position of the tuning element for each resonant cavity 4 that corresponds to the carrier frequency for the corresponding signal path. The tuning element for the resonant cavity 4 is tuned to the correct position at step 29. The loop counter is incremented at step 30. Steps 26, 27, 28, 29 are repeated for each signal path in turn until the resonant cavity 4 in the last path is tuned. At this point execution of step 25 results in the determination that the loop escape condition is met and the process ends at step 31.

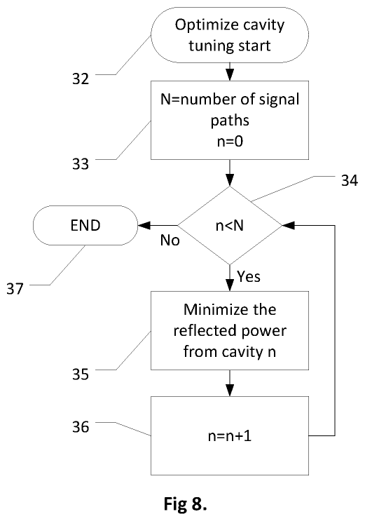

FIG. 8 shows the flowchart for the “optimize cavity tuning” sub-process. This process starts at step 32 when called by the main tuning algorithm (FIG. 6) or when the controller 9 (FIG. 1) detects that the reflected power from one or more resonant cavities 4 has exceeded a predefined threshold. The number of signal paths is defined and the loop counter is initialized at step 33. The tuning element of the first resonant cavity 4 is adjusted until the RF power reflected by the resonant cavity 4 is minimized at step 35. The loop counter is incremented at step 36. Steps 35 and 36 are repeated for each resonant cavity 4 until all the resonant cavities 4 have been adjusted. At this point execution of step 34 results in the determination that the loop escape condition is met and the process ends at step 37.

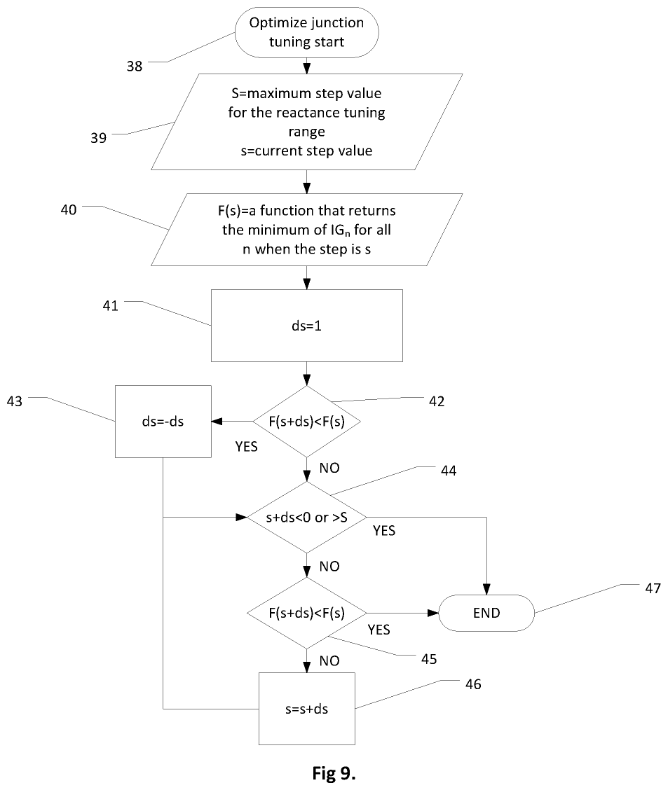

FIG. 9 is a flowchart of the “optimize junction tuning” sub-process. This process maximizes the function F(s) where F(s) returns the minimum value of the set {IGₙ} where the values (insertion gain of signal path n) IGₙ are determined when the tuning position of the reactive element 7 (FIG. 1) in the junction 6 is set to a value of s. This process starts at step 38 when it is called by the main tuning algorithm of FIG. 6. The maximum limit for the step value and the current step value is defined at step 39. F(s) is defined at step 40. An increment value ds is determined for the reactance at step 41. s is increased by ds and the new value of F(s) is determined. If this new value is lower than the first as determined at step 42, then the sign of ds is changed at step 43. ds is added to s repeatedly at step 46 and F(s) is determined for each value. This continues as long as F(s) is increasing at step 45. When a step is reached where F(s) is decreasing the iteration stops at step 47. An escape at step 44 is added to the algorithm to prevent the reactance of the reactive element 7 from being set to a value outside its tunable range.

Once the combiner is tuned, the controller 9 (FIG. 1) continues to monitor the signals from the directional couplers 3. If it detects a frequency change in one or more of the signal paths, it will initiate the tuning process again. If it detects reflected power from one of the resonant cavities 4 that exceeds a set threshold without detecting a frequency change in that signal path, it will adjust the tuning of that resonant cavity 4 to minimize the reflection.

Interface ports are provided on the control unit to allow the user to interface with the combiner by either connecting to it through a network or the internet or by connecting a computer directly to it. The user can monitor the various settings of the combiner as well as the signal power levels and frequencies. The user can set alarm conditions that would cause the controller 9 (FIG. 1) to send an alert message if any of the values monitored fall outside of their nominal range.

The self tuning transmitter combiner includes a number of resonant cavity filters 4 (FIG. 1) that correspond to the number of radios 1 to be combined, a corresponding number of isolators 2, directional couplers 3 and fixed electrical length transmission lines, a junction 6 with a tunable reactive element 7, an additional final directional coupler 8 at the output of the combiner, a control circuit to monitor and control the combiner, software that optimizes the tuning of the resonant cavity filters 4 and the reactive element 7 of the junction 6, and a graphical user interface (GUI) that allows the operator to interface with the combiner.

The isolators 2 (FIG. 1) prevent the RF (Radio Frequency) power directed into the combiner from being reflected back into the radios 1. The directional couplers 3 between the isolators 2 and the resonant cavities 4 may direct a small portion of the RF power transmitted into the resonant cavities 4 and reflected from the resonant cavities 4 into the controller 9. The resonant cavities 4 may be set to resonate at the frequency that corresponds to their signal path, facilitating the transmission of that frequency along the path while inhibiting the transmission of other frequencies. The transmission lines joining the resonant cavities 4 to the junction block 6, in concert with the reactive element 7 in the junction block 6, may transform the impedances of the resonant cavities 4 to maximize the throughput of the RF power through the junction block 6. The junction block 6 may provide multiple inputs for the transmission lines and a single output while acting as a housing for the tunable reactive element 7. The tunable reactive element 7 may be set to maximize the RF power throughput while minimizing reflections at the junction 6. The final directional coupler 8 at the combiner output directs a small portion of the RF power leaving the junction block 6 and reflected from the upstream circuit elements that are external to the combiner such as the load 10.

The controller 9 may be operable to perform one or more of the following functions:
a. Measures the signals coming from the directional couplers 3, 8 and determines the channel frequency and power level;
b. Tunes the resonant cavities 4 and the tunable reactive element 7 to minimize the power reflected from the resonant cavities 4 and to maximize the power output of the combiner;
c. Provides Ethernet connectivity for the combiner; and
d. Runs the internal software and hosts the GUI.

The software may be operable to perform one or more of the following functions:
a. Calculates various derived parameters for the RF signal paths such as return loss/VSWR and insertion loss; and
b. Optimizes the tuning of the resonant cavities 4 and the reactive element 7.

The GUI may be operable to perform one or more of the following functions:
a. Allows the operator to monitor the combiner operation and the frequencies and power levels of the signals passing through the combiner;
b. Allows the operator to manually override the tuning of the combiner and adjust the resonant cavities 4 and the reactive element 7; and
c. Allows the operator to set alarms for anomalous conditions and sub-optimal performance.

While embodiments of the invention have been described and illustrated, such embodiments should be considered illustrative of the invention only. The invention may include variants not described or illustrated herein in detail. Thus, the embodiments described and illustrated herein should not be considered to limit the invention as construed in accordance with the accompanying claims.

What is claimed is:

1. A self-tuning transmitter combiner, the combiner comprising:
(a) a junction for combining a plurality of signals transmitted along a plurality of signal paths comprising a plurality of filters, respectively, the junction comprising a reactive element; and
(b) a computer-implemented controller operable to tune the plurality of filters in accordance with a plurality of carrier frequencies of the plurality of signals, respectively, the controller being further operable to tune the reactive element such that a lowest insertion gain selected by the controller from a plurality of insertion gains respectively associated with the plurality of signal paths is maximized.

2. The combiner of claim 1 wherein the controller is operable to minimize a plurality of reflected powers of the plurality of filters by adjusting a plurality of cavity positions associated with the plurality of filters, respectively.

3. The combiner of claim 2 wherein the controller is operable to determine, in response to a respective said carrier frequency, a corresponding said cavity position by interpolation among a plurality of known cavity positions respectively associated with a plurality of known carrier frequencies.

4. The combiner of claim 1 wherein the controller is operable to set the reactive element to a midpoint tuning position of a range of tuning positions of the reactive element, and is operable to then determine a first lowest insertion gain.

5. The combiner of claim 4 wherein the controller is operable to determine a first plurality of insertion gains associated with the plurality of signal paths respectively extending from a plurality of direction couplers of the combiner, through the plurality of filters, through the junction, and then to an output directional coupler of the combiner, the controller being further operable to then select the first lowest insertion gain from the first plurality of insertion gains.

6. The combiner of claim 5 wherein the controller is operable to:
(c) set the reactive element to a new tuning position, within the range of said tuning positions, that is offset by a predetermined amount from a preceding tuning position of said tuning positions;
(d) determine a new plurality of said insertion gains in response to the new tuning position;
(e) determine a new said lowest insertion gain in response to the new plurality of said insertion gains; and
(f) iteratively repeat steps (c) to (e) until the new said lowest insertion gain is lower than a preceding said lowest insertion gain.

7. A method of tuning a combiner, the method comprising:
(a) by a computer-implemented controller, tuning a plurality of filters of a plurality of signal paths in accordance with a plurality of carrier frequencies of a plurality of signals being transmitted along the plurality of signal paths, respectively; and
(b) by the computer-implemented controller, tuning a reactive element of a junction for combining the plurality of signals, such that a lowest insertion gain selected from a plurality of insertion gains respectively associated with the plurality of signal paths is maximized.

8. The method of claim 7 wherein step (a) is performed before performing step (b), the method further comprising repeating step (a) after having performed step (b).

9. The method of claim 8 wherein step (a) comprises minimizing a plurality of reflected powers of the plurality of filters by adjusting a plurality of cavity positions of the plurality of filters, respectively.

10. The method of claim 9 wherein adjusting the plurality of cavity positions associated with the plurality of filters, respectively, comprises determining, in response to a respective said carrier frequency, a corresponding said cavity position by interpolating among a plurality of known cavity positions respectively associated with a plurality of known carrier frequencies.

11. The method of claim 10 further comprising repeating the step of respectively minimizing the plurality of reflected powers of the plurality of filters.

12. The method of claim 8 wherein step (b) comprises setting the reactive element to a midpoint tuning position of a range of tuning positions of the reactive element and then determining a first said lowest insertion gain.

13. The method of claim 12 wherein determining the first said lowest insertion gain comprises determining a first plurality of said insertion gains associated with the plurality of signal paths extending from a plurality of input directional couplers of the combiner, through the plurality of filters, respectively, through the junction, and then to an output direction coupler of the combiner, and further comprises selecting the first said lowest insertion gain from the first plurality of said insertion gains.

14. The method of claim 13 further comprising setting the reactive element to a second tuning position, within the range of said tuning positions, that is offset by a predetermined amount from the midpoint tuning position, and then determining a second plurality of said insertion gains associated with the plurality of signal paths, and then selecting a second said lowest insertion gain from the second plurality of said insertion gains.

15. The method of claim 14 further comprising changing the polarity of the predetermined amount if the second said lowest insertion gain is lower than the first said lowest insertion gain.

16. The method of claim 15 further comprising:
(c) setting the reactive element to a new tuning position, within the range of said tuning positions, that is offset by the predetermined amount from a preceding tuning position of said tuning positions;
(d) determining a new plurality of said insertion gains in response to the new tuning position;
(e) determining a new said lowest insertion gain in response the new plurality of said insertion gains; and
(f) iteratively repeating steps (c) to (e) until the new said lowest insertion gain is lower than a preceding said lowest insertion gain.

17. The method of claim 7 further comprising receiving, by the computer-implemented controller, user instructions indicating manual override and, in response to the user instructions, performing at least one computer-implemented action selected from: (g) adjusting a cavity position of a user-selected said filter; and (h) setting the reactive element to a user-selected tuning position within a range of tuning positions of the reactive element.

18. A self-tuning transmitter combiner, the combiner comprising:
(a) means for tuning a plurality of filters of a plurality of signal paths in accordance with a plurality of carrier frequencies of a plurality of signals being transmitted along the plurality of signal paths, respectively; and
(b) means for tuning a reactive element of a junction for combining the plurality of signals, such that a lowest insertion gain selected from a plurality of insertion gains respectively associated with the plurality of signal paths is maximized.
